(19) United States
(12) Patent Application Publication
(10) Pub. No.: US 2026/0059724 A1
(43) Pub. Date: Feb. 26, 2026

(54) Cooling an Electrical Module

(71) Applicant: Siemens Aktiengesellschaft, München (DE)

(72) Inventors: Volker Müller, Nürnberg (DE); Florian Schwarz, Gerhardshofen (DE); Stephan Neugebauer, Erlangen (DE); Thomas Bigl, Herzogenaurach (DE); Vladimir Danov, Erlangen (DE); Florian Reissner, Nürnberg (DE); Jörn Grundmann, Großenseebach (DE); Sherif Madkour, Berlin (DE)

(73) Assignee: Siemens Aktiengesellschaft, München (DE)

(21) Appl. No.: 19/302,425

(22) Filed: Aug. 18, 2025

(30) Foreign Application Priority Data
Aug. 22, 2024 (EP) 24195911.3

(51) Int. Cl. H05K 7/20

(52) U.S. Cl. CPC H05K 7/20927; H05K 7/20145; H05K 7/20163; H05K 7/20254; H05K 7/20272; H05K 7/20918

(57) ABSTRACT

Various embodiments of the teachings herein include an electrical module with an electrical component and a cooling apparatus to remove heat from the electrical component. An example includes: an annularly closed media channel to circulate a working medium in a closed circuit, the channel wall divided into a plurality of alternating hot segments and cold segments; a transition region formed between each pair of adjacent hot segments and cold segments; and at least one flow-directing element arranged in at least a subset of the transition regions defining a preferred direction for thermally driven transport of the fluid working medium by local heat input. Each of the plurality of hot segments is arranged approximate the electrical component and thermally coupled thereto to enable heat removal from the electrical component using local heat input into the fluid working medium via the respective hot segment of the channel wall.

### CROSS-REFERENCE TO RELATED APPLICATIONS

This application claims priority to EP application Ser. No. 24195911.3 filed Aug. 22, 2024, the contents of which are hereby incorporated by reference in their entirety.

### TECHNICAL FIELD

The present disclosure relates to electrical modules. Various embodiments of the teachings herein include electrical modules with at least one electrical component generating heat and a cooling apparatus for cooling the electrical component.

### BACKGROUND

A variety of cooling methods for electrical and electronic modules to dissipate waste heat from electrical components are used. Especially in the field of power electronic components, the dissipation of heat released during operation is becoming an increasingly important challenge due to the continuing trend toward higher performance combined with miniaturization of modules.

Air cooling is a relatively simple approach for cooling electrical modules. This typically entails circulating ambient air into the interior of a module housing via a fan built into the module in order to promote heat dissipation into the ambient air and thus remove the heat dissipated by the electrical components. This approach is frequently chosen for low-power electrical modules in the low-price segment. However, it is usually no longer possible to achieve sufficient heat dissipation for power electronics modules with higher power densities.

Liquid cooling is an alternative approach for cooling electrical modules. Liquid-cooled electrical modules are particularly common in industrial applications where power densities are higher and the cooling system requires correspondingly more complex equipment and is more expensive. Herein, typically some of the electrical components are thermally coupled to a heat sink. This heat sink contains cooling channels for circulating a liquid coolant, wherein the liquid coolant can absorb the heat from the heat sink and dissipate it into a region outside the module housing. For this purpose, the housing is correspondingly equipped with an inlet and an outlet for the liquid coolant. The coolant is generally pumped through the corresponding piping system by a pump located outside the module housing. Disadvantages of this approach include the number of module interfaces due to the additional coolant lines, the energy consumption of the external pump and the increased complexity of the internal structure of the module, wherein compatibility with the liquid coolant used also has to be taken into account to some extent when selecting materials. The greater complexity also often means that the maintenance requirements of such a liquid-cooled electrical module are higher than those of an air-cooled module.

Another known cooling method for electrical modules is based on the principle of heat pipes. In general, a heat pipe is a heat exchanger that allows high heat flux density by utilizing the evaporation enthalpy of a fluid working medium. Herein, the working medium circulates in a closed interior (cavity) in a closed circuit between an evaporator region and a condenser region. Herein, in the evaporator region, the working medium absorbs heat and changes from a liquid to a gaseous state and, in the condenser region, it releases heat and changes from a gaseous to a liquid state. Accordingly, a part of the heat pipe from which heat is to be removed is assigned to the evaporator region, and a part of the heat pipe that is to be heated is assigned to the condenser region. In this way, large amounts of heat can be transferred over a smaller cross-sectional area. In a conventional heat pipe, the condensed working medium is returned from the condenser region to the evaporator region by capillary transport through a capillary structure arranged inside the cavity.

A pulsating heat pipe (PHP) is a special type of heat pipe with a closed interior for transporting a fluid working medium in an independently pulsating operation, such as, for example, described in European patent application EP 3 823 018 A1. Therefore, here, in contrast to conventional heat pipes, return transport of the condensed working medium to the heat source is effected by independent pulsation of the working medium. In order to enable this, the interior of the heat pipe has a relatively narrow channel-like structure. The media channel formed is so narrow that the surface tension of the condensed working medium causes alternating, and in each case interconnected, segments of liquid and vapor to form. The vapor segments expand on the hot side of the heat pipe and shrink on the cold side of the heat pipe, wherein proportional condensation also takes place. As a result, there are always local temperature and pressure differences in the PHP which the two-phase system attempts to compensate by applying longitudinally displacing forces to the liquid and vapor segments. These compensating forces lead to a constant oscillating or pulsating motion the segments, of individual which is automatically established without any active external drive solely by the temperature difference and due to the surface tension within the media channel. In particular, the system never reaches a static equilibrium, instead the pulsation is maintained as long as there is a temperature difference and as long as there is a division into alternating longitudinal segments of liquid and vapor. This movement is also referred to as self-oscillating two-phase flow. Overall, significantly lower resistances can be achieved with such a PHP than with a conventional heat pipe. However, efficient heat transfer with such a two-phase system typically requires relatively complex and fine-grained structures with geometric specifications that must be adhered to very precisely during production in order to ensure the formation of the self-oscillating two-phase flow. Therefore, the manufacture of such PHPs is associated with a high outlay on equipment.

### SUMMARY

Teaching of the present disclosure include electrical modules that address the aforementioned disadvantages. In particular, some embodiments of the teachings herein include electrical modules with an alternative cooling apparatus that enable effective heat dissipation from the electrical components it contains at high power densities. This is in particular to be achieved with low equipment complexity, especially with regard to the module's external interfaces.

For example, some embodiments include an electrical module (30) with at least one electrical component (35) and a cooling apparatus (1) for cooling the electrical component (35), wherein the cooling apparatus (1) has an annularly closed elongated media channel (3) for circulating a fluid working medium (M) in a closed circuit, wherein the annularly closed media channel (3) is bounded by a channel wall (5), which is divided, at least in a partial region (40), in its local longitudinal direction (x), into a plurality of alternating hot segments (W) and cold segments (K), wherein the hot segments (W) are in each case arranged in the region of the at least one electrical component (35) and thermally coupled thereto in such a way that they enable heat to be removed from the electrical component (35) by means of local heat input (Qᵢₙ) into the fluid working medium (M) via the respective hot segment (W) of the channel wall (5), wherein a transition region (T) is formed between the adjacent hot segments (W) and cold segments (K) in each case, and wherein in each case at least one flow-directing element (7) is arranged in at least one subset of these transition regions (T) with which a preferred direction (r) can be imparted to a thermally driven transport of the fluid working medium (M) s by local heat input (Qᵢₙ).

In some embodiments, at least one of the electrical components (35) present is a semiconductor component.

In some embodiments, the electrical module (30) is designed as a converter module.

In some embodiments, the cold segments (K) of the channel wall (5) are in each case arranged in the region of a cooling element (37) and thermally coupled thereto in such a way that heat removal (Qₒᵤₜ) from the fluid working medium (M) is enabled by means of heat input into the cooling element (37) via the respective cold segment (K) of the channel wall (5).

In some embodiments, the elongated media channel (3) is filled with a fluid working medium (M) having a thermal expansion coefficient of at least 200·10⁻⁶ K⁻¹, wherein this thermal expansion coefficient of the working medium (M) is at least a factor of two higher than a thermal expansion coefficient of a material of the channel wall (5).

In some embodiments, the fluid working medium (M) has a thermal conductivity of at least 0.1 W/(m·K) and/or wherein the channel wall (5) is formed from a material with a thermal conductivity of at least 1 W/(m·K).

In some embodiments, the channel wall (5) is formed from an auxetic material.

In some embodiments, the alternating hot segments (W) and cold segments (K) in each case have a segment length relative to their local longitudinal direction (x), which lies in a range between 1 mm and 10 mm.

In some embodiments, the elongated media channel (3) has a channel width in a range between 0.1 mm and 4 mm.

In some embodiments, the at least one flow-directing element (7) is formed by a lamella aligned obliquely to the local longitudinal direction (x), by a Tesla valve and/or by a check valve.

In some embodiments, at least one longitudinal segment of the channel wall (5) is embodied as an intermediate segment (N) which connects a pair of hot segments (W) and/or cold segments (K) and which has a segment length that is greater than an average segment length of the hot segments (W) and cold segments (K).

In some embodiments, the channel wall (5) has a local recess in the region of at least one hot segment (W) via which the fluid working medium (M) can directly flow through the electrical component (35).

As another example, some embodiments include a cooling apparatus (1) for cooling at least one heat source (35), wherein the cooling apparatus (1) has an annularly closed elongated media channel (3) for circulating a fluid working medium (M) in a closed circuit, wherein the annularly closed media channel (3) is bounded by a channel wall (5), which is divided, at least in a partial region (40), in its local longitudinal direction (x), into a plurality of alternating hot segments (W) and cold segments (K), wherein the hot segments (W) are in each case arranged in the region of the at least one heat source (35) and are thermally coupled thereto in such a way that they enable heat to be removed from the heat source by means of local heat input (Qᵢₙ) into the fluid working medium (M) via the respective hot segment (W) of the channel wall (5), wherein a transition region (T) is formed between the adjacent hot segments (W) and cold segments (K) in each case, and wherein in each case at least one flow-directing element (7) is arranged in at least one subset of these transition regions (T) with which a preferred direction (r) can be imparted to a thermally driven transport of the fluid working medium (M) by local heat input (Qᵢₙ).

In some embodiments, the at least one electrical component (35) is cooled by means of a fluid working medium (M) which circulates within the elongated media channel (3) in a closed circuit, wherein the transport of the fluid working medium (M) is thermally driven by local heat input (Qᵢₙ), and wherein the transport takes place along a preferred direction (r), which is imparted by the at least one flow-directing element (7) into a material flow of the fluid working medium (M).

In some embodiments, the fluid working medium (M) embodies a single-phase material flow.

### BRIEF DESCRIPTION OF THE DRAWINGS

The teachings of the present disclosure are described below on the basis of some exemplary embodiments with reference to the attached drawings, in which:

FIG. 1 shows a schematic sectional view of a cooling apparatus incorporating teachings of the present disclosure;

FIG. 2 shows three different operating stages of such an apparatus;

FIG. 3 shows a schematic top view of an electrical module incorporating teachings of the present disclosure; and

FIG. 4 shows a schematic representation of the propagation of a thermally driven media transport.

In the figures, identical or functionally identical elements are designated by the same reference characters.

### DETAILED DESCRIPTION

An example electrical module incorporating teachings of the present disclosure has an electrical component and one cooling apparatus for cooling the electrical component, wherein the cooling apparatus has an annularly closed elongated media channel for circulating a fluid working medium in a closed circuit. The annularly closed media channel is bounded by a channel wall, which is divided, at least in a partial region in its local longitudinal direction, into a plurality of periodically alternating hot segments and cold segments. Herein, the hot segments are in each case arranged in the region of the at least one electrical component and thermally coupled thereto in such a way that they enable heat to be removed from the electrical component by means of local heat input into the fluid working medium via the respective hot segment of the channel wall. A transition region is formed between the adjacent hot segments and cold segments in each case, wherein in each case at least one flow-directing element is arranged in at least one subset of these transition regions with which a preferred direction can be imparted to a thermally driven transport of the fluid working medium by local heat input.

Therefore, the aforementioned hot segments and cold segments in each case form longitudinal segments of the channel wall, which encloses the overall elongated media channel. Herein, the media channel does not necessarily have to be straight, but can have curved sections and, for example, meander-like turns. However, it is advantageous for it to have an overall elongated shape that can be divided into a number of sections (the longitudinal segments). Accordingly, in each case a local longitudinal direction is defined for a local position of the media channel; hereinafter, this is also referred to as the axial direction. The hot segments are characterized by the fact that they are hotter than the cold segments between them when the electrical module is in operation. This is because they are arranged in the region of the existing electrical components; in particular, they have the same or overlapping position in the axial direction as an assigned electrical component in each case. The hot segments therefore in particular have a shorter distance and a closer thermal coupling to the existing electrical components than the cold segments. A hot segment is in each case assigned to an electrical component with which it is either in direct contact or to which it is connected via a thin highly heat-conductive intermediate element.

Overall, there can also be a plurality of electrical components from which heat is removed via the media channel and which are in each case assigned to one or more of the overall hot segments present. Therefore, heat is transported via the fluid working medium from the hot segments of the channel wall to the cold segments of the channel wall (which are cooler during operation). In the region of the hot segments, heat is input into the working medium and, in the region of the cold segments, heat is removed from the working medium. The heat extracted in the region of the cold segments is transferred via the channel wall, for example, to an adjacent cooling element that is assigned to the cold segment in a similar manner and is designed to dissipate heat to the environment of the electrical module.

Overall, there is a plurality of hot segments and a plurality of cold segments that alternate with one another, at least in a partial region of the entire length of the media channel. They can in particular alternate with one another in a periodic structure, i.e., in other words, in a recurring pattern. Herein, in particular, the length of the individual hot segments, the length of the individual cold segments and/or the distance between the centers of the longitudinal segments in each case can be constant over the partial region under consideration. The recurring pattern can have a fixed spatial repetition length with which an elementary cell of the pattern is periodically repeated in one dimension. Such a recurrent alternation of alternating hot segments and cold segments ensures that thermally driven media transport is established along the longitudinal direction of the media channel, similarly to the case with the above-described PHP. In contrast to a PHP, the media channel of the module according to the invention is not designed for a two-phase oscillating system, but for single-phase thermally inducted transport of the enclosed fluid working medium. Herein, therefore, the formation of phase boundaries is not intended, and accordingly, the cross section of the channel structure does not have to be adapted to the constraints of surface tension and capillary transport. Hence, the geometric tolerances can be wider and the production of the structures of the media channel can be less precise and thus simpler than is the case with a PHP.

Thermally driven media transport is established in that a thermal expansion of the working medium is effected in the hot segments by the heat input into the fluid working medium. In contrast, heat removal in the region of the cold segments causes the fluid working medium to contract. Compared to the fluid working medium, the channel wall is relatively rigid and in particular also less affected by volume changes due to thermal expansion or shrinkage. This means that the pressure gradient formed between the hot segments and cold segments can be primarily compensated by transporting the fluid working medium along the longitudinal direction of the media channel. Therefore, the temperature differences initially form the basis for a recurring pattern of pressure differences. This recurring pattern of pressure differences forms the basis for a self-sustaining pulsating motion because the movement of the working medium resulting from the compensation of the pressure differences is guided in a preferred direction by the flow-directing elements.

In each case, a transition region is formed between a pair consisting of a hot segment and an adjacent cold segment. In each case, one or more flow-directing elements are arranged in at least one subset of these transition regions (per transition region). Such a flow-directing element causes the level of flow resistance for the working medium to depend on the +/− signs of the axial direction of movement (axial with regard to the local longitudinal direction of the media channel). The flow resistance is therefore lower for the preferred direction than it is for the opposite direction, and overall, net media transport is established through the entire annular media channel with a +/− sign determined by the geometry of the flow-directing elements present. For example, an obliquely aligned lamella, a nozzle and/or a Tesla valve can be used as the flow-directing element. Overall, there can be a plurality of such flow-directing elements. For example, one or more flow-directing elements can be arranged as part of a recurrent pattern in the respective transition region between adjacent hot and cold segments. In addition to the aforementioned transition regions, such flow-directing structures can also be arranged within the hot and/or cold segments in order to more effectively impart a preferred direction to the transport of the working medium.

Overall, the arrangement of alternating hot and cold segments with the flow-directing structures between them does not necessarily have to extend over the entire longitudinal extension of the media channel. For example, it is generally sufficient if the media channel is only structured in the manner described in a partial region of its longitudinal extension. Net media transport along the preferred direction formed can initially develop in a thermally induced manner in this partial region and then propagate from them over the entire length of the media channel until a stable longitudinal flow develops along this preferred direction. Overall, this results in a self-sustaining flow of the working medium along the media channel, which, unlike the case with PHPs, is also established in a single-phase system.

The above-described thermally induced transport mechanism for the fluid working medium can in particular be purely passively driven, i.e., in other words, without the influence of actively moving drive structures, such as pumps or microelectromechanical actuators (MEMS actuators). Rather, the driving force for the flow results solely from the contractions and/or expansions of the materials due to local temperature changes. Similarly to intestinal peristalsis, this type of thermally induced longitudinal flow can also be referred to as peristalsis-like transport. However, in contrast to intestinal peristalsis, here there are no external actuators (which are provided by contracting muscles in the intestine) and therefore it is also possible to use the term “passively induced peristalsis”. If the heat dissipation from the components from which heat is to be removed and the heat absorption of the cooling elements are constant over time, consistent axial flow of the working medium can be established gradually due to the passively induced fluid transport. However, it is even more advantageous if a pulsating longitudinal flow is established in which a wave-like spatial temperature profile with a pattern of alternating hot and cold zones of the working medium moves annularly along the media channel. In principle, such a pulsating temperature profile can be established due to the pattern of hot and cold segments in interaction with the flow dynamics of the working medium. However, such a pulsating flow can be reinforced by pulsating heat input. Many electronic components do not dissipate their power losses continuously, but in a time-varying manner. If a predominant frequency is imposed on the temporal variation, this frequency can be imposed on both the heat input and the pulsating transport of the working medium. In this way, similarly to the case with PHPs, a pulsating flow can be induced purely thermally and without moving drive elements. However, here, in contrast to the case with PHPs, this pulsating fluid flow is realized in a single-phase fluid system.

An electrical module as described herein uses the transport mechanism described to provide effective heat transport between the hot segments and the cold segments of the media channel. This achieves effective heat removal from the electrical components present, for example, via a cooling element coupled to the cold segments. Herein, the thermally induced fluid transport can be achieved with geometric structures, which are relatively simple compared to other cooling apparatuses, such as, for example, a PHP, and require less geometric precision.

Another example individual cooling apparatus may be designed for cooling one or more heat sources and otherwise has features analogous to those of the cooling apparatus of the above-described electrical module. The heat sources that can be cooled by such a cooling apparatus can then likewise be one or more electrical components or other types of components from which heat is to be removed.

The methods described herein may be used to operate an electrical module incorporating teachings of the present disclosure. Therein, the at least one electrical component is cooled by means of a fluid working medium that circulates within the elongated media channel in a closed circuit. The transport of the fluid working medium is thermally driven by local heat input, and this transport takes place along a preferred direction, which is imparted by the at least one flow-directing element into a material flow of the fluid working medium. The advantages of the methods incorporating these teachings are analogous to the above-described advantages of the electrical modules.

In an analogous manner, a method for operating a cooling apparatus may include cooling at least one heat source by means of a fluid working medium, which circulates within the elongated media channel in a closed circuit. Here, once again, the transport of the fluid working medium is thermally driven by the local heat input and the transport takes place along a preferred direction, which is imparted by the at least one flow-directing element into a material flow of the fluid working medium. The described embodiments of the electrical module can also be realized with the cooling apparatus and the operating method, and vice versa.

For example, at least one of the electrical components present in the electrical module can be a semiconductor component. The module is then in particular an electronic module. In general, it can contain a plurality of such active components, in particular semiconductor chips with integrated circuits, and additionally also passive components, such as capacitors and resistors. All these electrical components release heat during operation due to power losses, and this heat can be dissipated or at least spatially distributed (spread) particularly simply and effectively with the embodiment of the cooling apparatus according to the invention.

The electrical module can be designed as a power electronics module and in particular as a converter module. Here, a converter module should be understood to be an electrical device designed to convert an input current into an output current by changing at least one parameter. Overall, it can therefore be an electrical module that functions as a rectifier for converting alternating current into direct current, an inverter for converting direct current into alternating current, a DC/DC converter for converting direct current into another type of direct current or a converter (AC/AC converter) for converting alternating current into a different type of alternating current. This conversion in particular takes place by means of electronic components based on semiconductor materials, so-called power semiconductors. During operation, these typically exhibit particularly high power loss, so that it is also possible to accept a certain amount of additional manufacturing effort for the structures designed in order to ensure effective cooling.

In some embodiments, the cold segments of the channel wall are in each case arranged in the region of an assigned cooling element, in particular with the same axial position and/or axial spatial overlap. Herein, overall, there can also be a plurality of such cooling elements. The respective cooling element is thermally coupled to one or more assigned cold segments in such a way that heat removal from the fluid working medium flowing through the media channel is enabled. Herein, heat input is input from the working medium into the cooling element via the assigned cold segments of the channel wall in each case. The cooling element can in principle have different designs. The only essential feature is that this enables heat removal from the working medium so that overall heat distribution of the heat loss and cooling of the electrical components is achieved. In particular, the at least one cooling element can be designed to remove heat to the external environment of the electrical module. Herein, various secondary cooling mechanisms can be used.

In some embodiments, the cooling element can be designed as a heat sink, which in particular has a surface-enlarging structure on a side facing away from the media channel. This structure enlarges the surface area compared to a flat surface area and in this way increases the heat dissipation from the heat sink to the environment, for example to ambient air or another fluid coolant flowing toward the heat sink. The surface-enlarging structure can in particular have a plurality of cooling fins or consist of such cooling fins. In some embodiments, other surface-enlarging structures, such as cooling stars, cooling vanes, cooling columns and/or so-called pin fins can also be used.

In some embodiments, the at least one cooling element can also be a simple metallic feedthrough. Such a metallic feedthrough can, for example, be an elongated element and lead to a side of a printed circuit board contained in the electrical module that faces away from the component. Such feedthroughs are often referred to a “vias” in electrical engineering and can likewise be used for heat distribution when thermally coupled to the cold segments of the channel wall. Herein, there is a plurality of metallic feedthroughs, which, for example, can in each case be assigned to one or more cold segments and thermally coupled thereto.

In some embodiments, the cooling element can be the thermally coupling element of a heat exchanger. Such heat exchangers are sometimes also referred to as heat transfer devices and enable the transfer of thermal energy from one material flow to another; in this case from the fluid working medium of the described media channel to a further fluid coolant. This further fluid coolant can flow toward a side of the cooling element facing away from the media channel and, in principle, circulate in a closed circuit or be guided along this in an open flow. The heat exchanger can, for example, be designed for operation according to the countercurrent principle, the concurrent principle or the crosscurrent principle.

In general, and independently of the precise embodiment of the cooling element, thermal coupling to the assigned cold segment (or a plurality of assigned cold segments) can be achieved either by direct contact with the cold segment of the channel wall or via a thin highly heat-conducting intermediate element, similarly to the coupling of the hot segments to the electrical component. Furthermore, the cooling elements present can generally be formed of a metallic material.

When the electrical module is ready for operation, the elongated media channel can generally be filled with a fluid working medium. Herein, the media channel can in particular be encapsulated in a fluid-tight manner against the external environment so that the working medium circulates in a closed media circuit. Example working media are acetone, ammonia, ethanol, or water. The working medium is “fluid” in the sense that it is in a liquid, gaseous or supercritical state. In some embodiments, the working medium is in a single-phase state at the operating temperature of the module, in particular in a liquid or gaseous state. Herein, a liquid material flow may achieve particularly low thermal resistance.

However, a gaseous material flow can also have advantages with regard to the thermal expansion coefficient and/or the formation of a self-sustaining thermally induced flow.

In some embodiments, the working medium has a volumetric thermal expansion coefficient of at least 200·10⁻⁶ K⁻¹. Herein, the thermal expansion coefficient of the working medium is in particular at least a factor of two higher than a thermal expansion coefficient of a material of the channel wall. In some embodiments, the factor is even at least 10 and in particular even at least 50. Thus, the volumetric thermal expansion coefficient of the channel wall can, for example, be at most 100·10⁻⁶ K⁻¹. In some embodiments, the channel wall can be formed from aluminum with a linear thermal expansion coefficient of approximately 23·10⁻⁶ K⁻¹, and the working medium can be acetone with a linear thermal expansion coefficient of approximately 1460·10⁻⁶ K⁻¹. Herein, the volumetric expansion coefficient is approximately three times the specified linear expansion coefficients. The specified values in each case refer to temperatures in the range of room temperature, wherein the operating temperature of the media channel can generally also deviate therefrom and in particular can be higher. The selection of a working medium with a higher expansion coefficient than the channel wall is advantageous in order to promote longitudinal transport of the coolant induced by local heat input in the region of the hot segments. If, due to the heat input, the channel wall expands less than the working medium it encloses, local overpressure arises in the respective hot segment and this can drive the material transport in the direction of an adjacent cold segment. If the factor between the thermal expansion coefficient is relatively high and the elasticity of the channel wall is low, the surrounding channel wall can be considered to be almost rigid compared to the expanding working medium therewithin.

In some embodiments, the fluid working medium has a thermal conductivity of at least 0.1 W/(m·K). Many liquids, but also selected gases, achieve a value in this range. A relatively high thermal conductivity may be used to achieve low thermal resistance across the media channel. However, since the essential heat transport occurs through thermally induced flow and not only through heat conduction, it is also possible to use working media with lower thermal conductivities, for example, in the range between 0.01 W/(m·K) and 0.1 W/(m·K).

In some embodiments, the channel wall is formed from a material with a thermal conductivity of at least 1 W/(m·K). In principle, this can relate to the hot segments and the cold segments of the channel wall, which may be formed with an overall consistent channel wall material. The wall thickness of the channel wall can also be selected to be consistent overall and, for example, lie in a range between 0.1 mm and 3 mm. A channel wall designed in such a way enables effective heat input from the electrical component into the interior of the media channel and/or effective heat removal from the working medium into the cooling element optionally coupled to the cold segments. In principle, however, the channel wall does not have to have a consistent thickness, in particular, the media channel can also be defined as a complex meander-like structure within an (otherwise solid) body. However, then the above-specified advantageous range for the wall thickness is nevertheless applicable to the maximum distance between the internal working medium and the external element from which heat is to be removed or the cooling element.

In some embodiments, the channel wall can be formed from an auxetic material. An auxetic material is characterized by a negative Poisson's ratio so that, when stretched, it expands transversely to the direction of stretching. This effect can cause local heat input due to resulting longitudinal stretching of the channel wall to lead to local narrowing of the internal media channel or at least to a reduction in the thermal expansion of the inner diameter resulting from the heat input without this effect. Due to such “relative narrowing” of the media channel, an auxetic material can contribute to additionally promoting the thermally induced axial material transport.

The alternating hot segments and cold segments can in each case have a segment length relative to their local longitudinal direction, which lies in a range between 1 mm and 10 mm. In particular, the segment lengths of the individual hot segments can be the same, and the segment lengths of the individual cold segments can also be the same. Furthermore, the cold segments can have the same segment lengths as the hot segments between them. Herein, the corresponding length of the transition regions can be relatively short and, for example, only be a fraction of the segment length of the hot and/or cold segments. Accordingly, a spatial repetition length for a periodically repeating sequence consisting of a hot segment, a transition region, a cold segment and a further transition region can lie within a range between 2 mm and 25 mm.

In some embodiments, the total number of hot segments can in particular be equal to the total number of cold segments, however, this is not mandatory and the recurrent arrangement of alternating hot and cold segments can, for example, also have gaps in which individual hot or cold segments are missing. However, such gaps have the advantage that the spatial repetition length of a recurring spatial sequence is not interrupted; rather a hot or cold segment is simply replaced by a so-called neutral intermediate segment representing neither a heat source nor a heat sink for the interior of the media channel.

In general, a relatively larger partial region of the channel wall can also be embodied as such a neutral intermediate segment, which correspondingly spatially connects a pair of two hot segments, a pair consisting of two cold segments or a pair consisting of one cold and one hot segment. Herein, the segment length of the neutral intermediate segment can in particular be greater than the average segment length of the individual hot and cold segments. In such a case, the segment length of the intermediate segment may be selected such that it corresponds to a multiple of the spatial repetition length of a periodically recurring sequence of adjacent hot and cold segments so that the periodic sequence is only interrupted, but not disturbed. Then, thermally induced media transport can propagate particularly effectively into the neutral intermediate segment and pulsating media transport can be established throughout the entire annularly closed media channel, without the frequency of this pulsating media transport being disturbed by the neutral intermediate segment. There can also be a plurality of neutral intermediate segments. However, in general, at least 50% of the longitudinal extension of the media channel may be covered by the above-described hot and cold segments in order to be able to drive effective media transport along the longitudinal direction of the channel with the resulting temperature differences.

In some embodiments, the elongated media channel can have a width in a range between 0.1 mm and 4 mm. For example, the media channel can have a circular cross section and the channel diameter can be within in this range. In some embodiments, the channel can also have a rectangular cross section or another cross section, and both the smallest and the largest expansion of the media channel (in the transverse direction) can be within the aforementioned range. Accordingly, the cross-sectional area of the media channel can be in a range between 0.01 mm² and 16 mm². Such dimensioning of the channel cross section may ensure effective heat transfer between the hot segments and cold segments and keep the costs associated with the production of the media channel within reasonable limits. In particular, herein, it is not necessary to adhere precisely to predetermined geometry. The shape and size of the channel cross section can, for example, be substantially constant over the length of the media channel, wherein local deviations in the shape and size dure to production or design do not have any significant negative effects.

There are various conceivable embodiments for the at least one flow-directing element or the plurality of flow-directing elements. In some embodiments, a flow-directing element can be embodied as a lamella aligned obliquely to the local longitudinal direction. Such a lamella can be formed from the same material as the channel wall and in particular formed in one piece with the channel wall. For example, such lamellae can be embodied in pairs opposite each other on partial regions of the channel wall. For example, they can lie above and below or to the right and left of a main flow of the working medium. Due to their oblique arrangement, such flow lamellae can contribute to imparting a preferred direction to the media flow. They can be designed as rigid lamellae or alternatively also formed from a flexible material (such as a thin metal or a plastic). A flexible embodiment enables a pulsating media flow to be promoted particularly effectively along a preferred direction, since the lamellae then act as a type of check valve.

As an alternative to such (individual or paired) lamellae, the transition regions can also have one or more nozzles for imparting a preferred direction. In the region of such a nozzle, the cross section of the internal media channel can be narrow overall (symmetrically or asymmetrically) along the preferred direction.

In general, the flow-directing element can be designed as a check valve, i.e., as a valve that allows the working medium to flow predominantly in one direction. For this purpose, the check valve can have one or more moving parts, i.e., a flexible check flap as in the human heart or a similar backflow-inhibiting structure. However, the blocking effect does not have to be complete in the reverse direction; it is, for example, sufficient to impart a preferred direction for the check valve to reduce a reverse flow by a few percent to a few tens of percent compared to a forward flow. Especially, if overall a large number of check valves is arranged in the media channel, a preferred direction can still be effectively imparted to the media flow. This also applies analogously to the other types of flow-directing elements.

A further suitable flow-directing element is a Tesla valve, which is functionally a passive variant of a check valve without moving parts. The introduction of an additional loop into an overall elongated media channel can achieve directional dependence of the flow resistant through suitable shaping in the branching and the confluence regions.

In some embodiments, the channel wall can have a local recess in the region of at least one hot segment via which the fluid working medium can directly flow through the electrical component. In particular, the working medium can directly flow through an electrically active sub-element of the electrical component, i.e., in particular a semiconductor material, an electrode material and/or a conductor material of an electrical resistor. This direct coupling of a heat source to the working medium achieves even more heat removal from the electrical component. Expediently, the working medium is then formed from an electrically insulating material in order to prevent unwanted electrical contact with the component via the working medium. In some embodiments, the fluid working medium can directly flow through an optional cooling element through one or more local recesses in the assigned cold segment of the channel wall. Even more effective heat input into this cooling element can be effected in an analogous manner.

In some embodiments, the fluid working medium can embody a single-phase material flow during operation of the electrical module or the cooling apparatus. Therefore, in contrast to a pulsating heat pipe, there is no alternating evaporation and condensation. Although the evaporation enthalpy cannot then be used for heat transfer, the requirements for geometric precision in the media channel geometry are lower. The embodiment of a stable media flow that has been imparted a preferred direction can nevertheless achieve relatively low thermal resistance between the hot segments and the cold segments of the channel wall. In addition, material transport, and thus also heat transport, in a single-phase system is less influenced by local density differences. As a result, material transport is also less dependent on spatial orientation in the gravitational field. Furthermore, other working media can be used in a single-phase system and the selection of suitable materials can be more flexible in some circumstances.

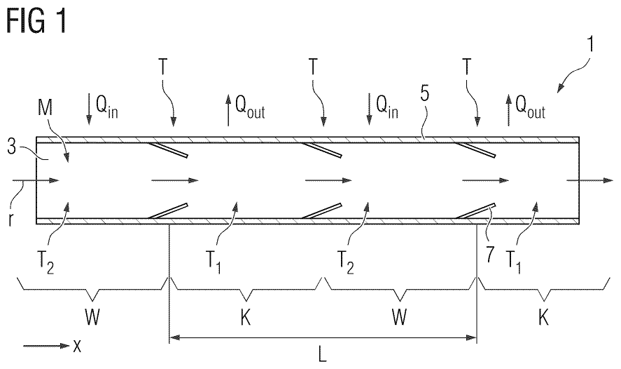

FIG. 1 shows a partial region of a cooling apparatus 1 in schematic longitudinal section. This figure shows a section of an overall elongated media channel 3, which is bounded by a channel wall 5. The section shown is a partial region of an overall annularly closed media channel 3, in which a fluid working medium M can circulate in a closed circuit. Therefore, the fluid working medium M, which can be a liquid, for example, is located within the media channel 3. A suitable working medium M is, for example, acetone. The section of the media channel 3 shown has a local longitudinal direction; here this is designated by x and is also referred to as the axial direction. Herein, the media channel 3 does not have to be rotationally symmetrical, and, in addition to a circular cross section, other cross-sectional shapes, for example, rectangular cross-sectional shapes with or without rounded corners are also conceivable.

The media channel 3 is bounded on all sides by a channel wall 5, which can be formed from a relatively highly heat-conductive material and in particular from a metallic material. A suitable material is, for example, aluminum or an aluminum-based alloy. The channel wall 5 is divided, in its local longitudinal direction x, into alternating hot segments W and cold segments K. The transition regions in between are designated by T. Herein, therefore, the hot segments W do not have to directly border the adjacent cold segments K (as shown here); it is also possible for a certain gap to be provided between these longitudinal segments. Neither must the individual hot and cold segments W, K be separated from one another by clear boundaries. They mainly differ in that the individual hot segments W are assigned to one or more elements from which heat is to be removed and are thermally coupled thereto. These elements from which heat is to be removed are not shown in detail here, but only represented by the heat input Qᵢₙ emanating from them. Such an element from which heat is to be removed can in particular be an electrical component such as, for example, a semiconductor component, an electrical resistor or the like. Such a component can in particular be in direct contact with the channel wall 5 in the region of a hot segment W or thermally coupled to the channel wall 5 via a thin highly heat-conductive intermediate element (such as, for example, a metallic carrier plate). In particular, the element from which heat is to be removed has the same or at least overlapping position in the x-direction as the assigned hot segment W. The distance between the hot segment W of the channel wall 5 and the element from which heat is to be removed that is assigned in each case can, for example, be below 2 mm in order to effect the closest possible thermal coupling.

In an analogous manner, the individual cold segments K are assigned to one or more cooling elements that function as heat sinks in the cooling apparatus. The cooling elements are also not shown in detail here; they are only represented by the heat output Qₒᵤₜ transferred to them from the respective cold segment K. Such a cooling element can, for example, be a heat sink with cooling fins for removing heat to the ambient air or a heat exchanger with a secondary coolant or a pulsating heat pipe or another type of cooling element with a secondary cooling mechanism for dissipating heat from the region of the media channel 3. The positioning of the respective cooling element relative to the assigned cold segment K, the thermal coupling and the distance can be designed analogously to that described above in connection with the hot segments W and the assigned elements from which heat is to be removed. In particular, at least one element from which heat is to be removed is assigned to each hot segment W, and at least one cooling element is assigned to each cold segment K.

The alternating sequence of hot segments W and adjacent cold segments K overall forms a recurring pattern with a spatial repetition length L. This recurrent sequence does not have to extend over the entire length of the media channel 3, it only has to extend over at least a partial region. Advantageously, such a recurrent sequence is embodied over the majority of its overall length.

Here, flow-directing elements 7 are in each case arranged in the transition regions T, which are located in the boundary region between the adjacent hot segments W and cold segments K. In the example shown, these are in particular guide lamellae 7, which are arranged in pairs opposite each other in the respective transition region. These guide lamellae 7 can in particular be formed from the same material as the rest of the channel wall 5 and merge into it in one piece. In some embodiments, they can also be formed from a different material. They can, for example, be formed by etching, milling, injection molding, mechanical forming using press tools and/or an additive manufacturing process.

In some embodiments, the flow-directing elements 7 can be arranged in a plurality of such transition regions T and/or in all such transition regions T within the recurrent sequence. They serve to impart a preferred direction r to a flow of the fluid working medium M embodied within the media channel 3. Therefore, the flow resistance through the transition region is lower along the preferred direction r than it is in the opposite direction. This allows a higher-level net material flow of the working medium in the closed media circuit along the preferred direction r.

The recurrent alternation of hot segments W and cold segments K promotes a thermally induced embodiment of such a material flow. In particular, such a thermally induced material flow does not require any pumps or other active drive means. The driving force for such a self-sustaining material flow lies in the temperature differences between the sections of the media channel 3 within the hot segments W and the cold segments K. Herein, the temperature of the working medium M within a cold segment K is designated by T₁ and the temperature of the working medium M within a hot segment M is designated by T₂.

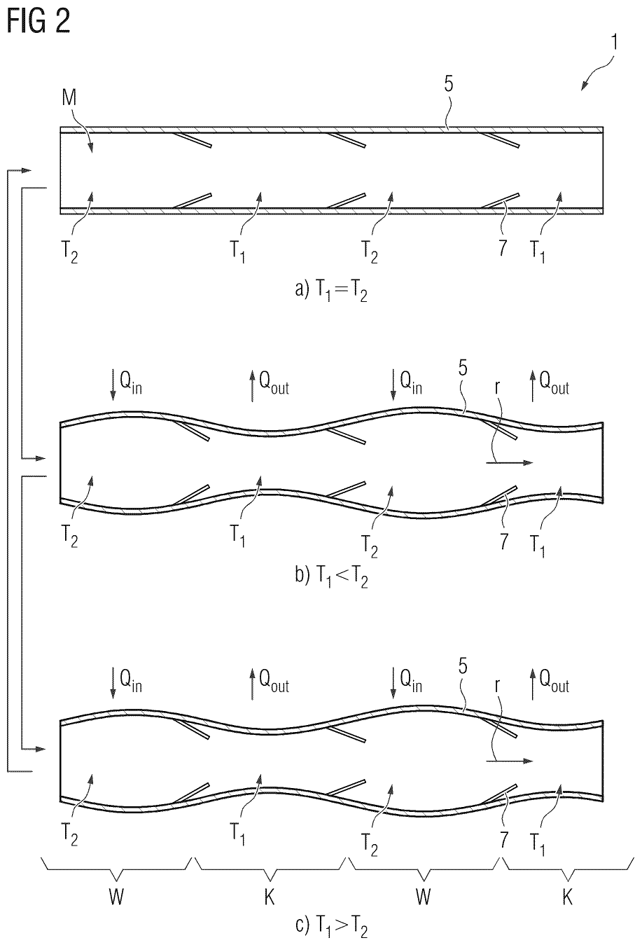

FIG. 2 shows a schematic outline of three different operating stages a) to c) of such an apparatus 1 in order to illustrate the self-sustaining material flow along the preferred direction r. In the first stage a), the temperatures T₁ and T₂ are substantially the same. Therefore, this corresponds to an initial stage before the heat flows Qᵢₙ and Qₒᵤₜ have begun and before the material transport has started. In the subsequent stage b), heat input Qᵢₙ into the working medium M via the hot segments W of the channel wall 5 and heat output Qₒᵤₜ from the working medium via the cold segments K has already taken place. As a result, the temperature T₂ within the hot segments W is higher than the temperature T₁ within the cold segments K. In the region of the hot segments W, this leads to thermal expansion of both the channel wall 5 and the internal working medium M. If the thermal expansion coefficient of the working medium M is higher than that of the material of the channel wall, the interior of the media channel expands to a greater extent than the surrounding channel wall 5, as indicated in FIG. 2 at stage b) by a convex bulge in this region. However, this bulge is greatly exaggerated and primarily symbolizes the local pressure increase inside the media channel 3 in the region of the hot segments W. In particular, the medium pressure in the region of the hot segments W in this region is higher than it is in the region of the adjacent cold segments K. In order to compensate this pressure difference, the working medium M can in principle flow from a given hot segment to the right or left. However, the flow-directing elements 7 favor the flow of medium to the right, along the preferred direction r. Therefore, overall, a net flow of the working medium M in this direction is established as a compensating movement.

The lower part of FIG. 2 shows a subsequent operating stage c), wherein the working medium M has been transported overall by a net total of half the repetition length within the annular media channel. In this stage, this annular transport now causes the temperature T₂ to be lower within the hot segments W than the temperature T₁ within the cold segments K. The temperature distribution of the stage b) is therefore approximately inverted. Due to these reversed temperature conditions, significantly more effective heat input Qᵢₙ into the hot segments W and more effective heat output Qₒᵤₜ from the cold segments K can now take place. The media transport in the x-direction resulting from the thermally induced flow therefore contributes to effective heat distribution in this spatial direction and, overall, to a reduction of the thermal resistance between the at least one element from which heat is to be removed, which is thermally coupled to the hot segments W and the at least one cooling element, which is coupled to the cold segments K. Hence, overall, particularly effective heat removal from one or more elements from which heat is to be removed can be effected.

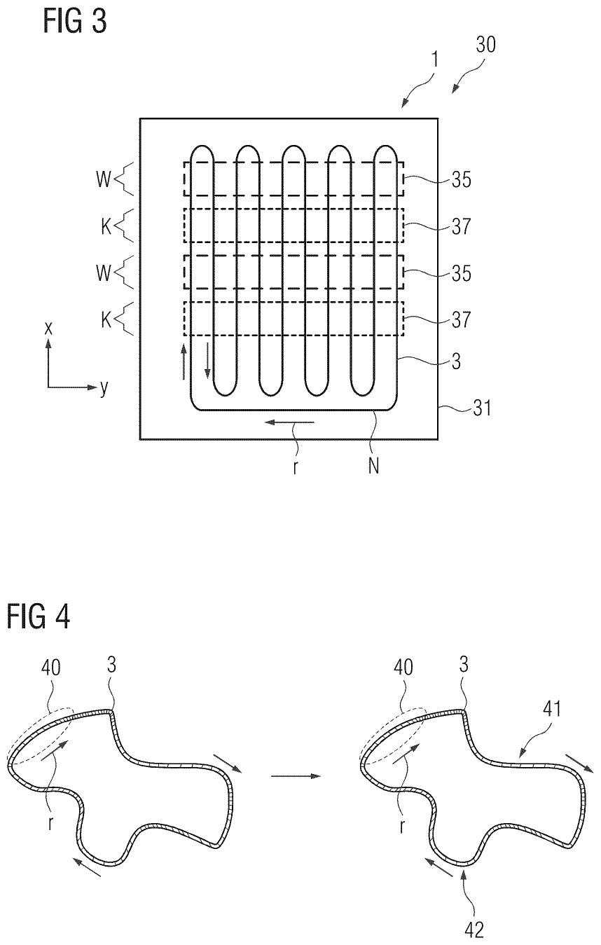

FIG. 3 shows a schematic top view of an electrical module 30. This electrical module 30 has a flat carrier plate 31 on which one or more electrical components 35 of the module 30 are arranged. By way of example only, two electrical components 35 are depicted here. In addition, the module has, for example, two cooling elements 37, which are designed to dissipate heat to the environment.

To remove heat from the components 35, the module 30 has a cooling system 1, which overall operates according to the same principle as described above in connection with FIGS. 1 and 2. This shows a top view of the xy plane, which contains a flat meander-like structure of an annular media channel 3 lying in the main plane of the carrier plate 31. Therefore, the media channel 3 is formed by a recess in the carrier plate. Herein, in principle, the electrical components 35 and the cooling elements 37 can be arranged above and/or below the drawing plane (i.e., the plane of the meander-like media channel). In this top view, for the sake of clarity these are only shown together with the other elements, and the dashed borders indicate the different positions relative to the z-direction (not shown here). Herein, the electrical components 35 can, for example, be arranged on a different side of the channel plane relative to the z-direction than the cooling elements 37. However, in principle, they can also be located on the same side (i.e., both above or both below the drawing plane).

Purely by way of example, here, five meander-like turns are shown for the media channel 3, wherein the actual number of turns in a real module can also be significantly higher. The meander-like turns result in a plurality of parallel longitudinal segments aligned in the x-direction. In this example, each of these longitudinal segments has a sequence consisting overall of two hot segments W and two cold segments K. Here, once again, the number of individual segments W, K within such a longitudinal segment of the media channel 3 can actually be significantly higher. The only essential feature is that, overall, there are one or more partial regions of the media channel 3 in which such an alternating sequence of hot segments W and cold segments K is embodied. Here, in the transition regions of the adjacent segments, flow-directing structures are also arranged on the channel wall (not shown in this schematic diagram). This results in a thermally induced material flow along the preferred direction r during operation of the electrical module 30, here, for example, net clockwise within the xy plane.

The flow along this preferred direction r propagates through the entire media channel 3, even if only partial regions thereof are covered by the recurring pattern of alternating hot segments W and cold segments K. For example, in particular, the lower return branch of the meander-like media channel 3 forms a neutral intermediate segment N, which is not assigned to either an element from which heat is to be removed 35 or a cooling element 37. Despite this interruption in the recurrent sequence, the flow of the media stream can propagate from the adjacent longitudinal segments across the entire annular media channel 3 and thus also continue into this neutral intermediate segment N.

FIG. 4 is a schematic outline of how a thermally induced media flow can continue from a partial region 40 via a higher-level annular media channel 3. For example, in the stage shown on the left, media transport is initially induced along the preferred direction r in a partial region 40 that has an alternating pattern of hot and cold segments. However, since the material flow of the fluid working medium M continues and is compensated over the entire annular media channel 3, individual regions of the working medium with relatively high local temperatures and individual areas of the working medium with relatively low local temperatures can also propagate to distant regions of the media channel 3 without the pattern imparted in the partial regions 40 being lost. By way as example only, here 41 denotes a local contraction zone with a relatively low temperature of the working medium and 42 denotes a local expansion zone with a relatively high temperature of the working medium. Both local zones have formed in partial region 40 and have propagated to distant sections of the media channel 3 due to the annular material flow along the preferred direction r.

### LIST OF REFERENCE CHARACTERS

1 Cooling apparatus
3 Elongated media channel
5 Channel wall
7 Flow-directing element (guide lamella)
30 Electrical module (converter module)
31 Flat carrier plate
35 Electrical component
37 Cooling element
40 Partial region of the media channel
41 Contraction zone
42 Expansion zone
a)-c) Stages of the operating method
K Cold segment
L Repetition length
M Working medium
N Neutral intermediate segment
Qᵢₙ Heat input
Qₒᵤₜ Heat removal
W Hot segment
r Flow direction (preferred direction)
T Transition region
T₁ First temperature
T₂ Second temperature
x Axial direction (local longitudinal direction)
y Lateral direction

1. An electrical module with an electrical component and a cooling apparatus to remove heat from the electrical component, the electrical module comprising:
an annularly closed elongated media channel to circulate a fluid working medium in a closed circuit, the annularly closed media channel bounded by a channel wall divided, at least in a partial region, in its local longitudinal direction into a plurality of alternating hot segments and cold segments;
wherein each of the plurality of hot segments is arranged approximate the electrical component and thermally coupled thereto to enable heat removal from the electrical component using local heat input into the fluid working medium via the respective hot segment of the channel wall;
a transition region formed between each pair of adjacent hot segments and cold segments; and
at least one flow-directing element arranged in at least a subset of the transition regions defining a preferred direction for thermally driven transport of the fluid working medium by local heat input.

2. The electrical module as claimed in claim 1, wherein the electrical component comprises a semiconductor component.

3. The electrical module as claimed in claim 2, wherein ht electrical module comprises a converter module.

4. The electrical module as claimed in claim 1, wherein each of the cold segments is arranged in approximate a cooling element and thermally coupled thereto to enable heat removal from the fluid working medium by means of heat input into the cooling element via the respective cold segment of the channel wall.

5. The electrical module as claimed in claim 1, further comprising a fluid working medium within the elongated media channel, the fluid working medium having a thermal expansion coefficient of at least 200·10⁻⁶ K⁻¹;
wherein the thermal expansion coefficient of the working medium is at least a factor of two higher than a thermal expansion coefficient of a material of the channel wall.

6. The electrical module as claimed in claim 5, wherein the fluid working medium has a thermal conductivity of at least 0.1 W/(m·K) and/or wherein the channel wall is formed from a material with a thermal conductivity of at least 1 W/(m·K).

7. The electrical module as claimed in claim 1, wherein the channel wall comprises an auxetic material.

8. The electrical module as claimed in claim 1, wherein each of the alternating hot segments and cold segments have a segment length relative to their local longitudinal direction in a range between 1 mm and 10 mm.

9. The electrical module as claimed in claim 1, wherein the elongated media channel has a channel width in a range between 0.1 mm and 4 mm.

10. The electrical module as claimed in claim 1, wherein the at least one flow-directing element comprises a lamella aligned obliquely to the local longitudinal direction, a Tesla valve, and/or a check valve.

11. The electrical module as claimed in claim 1, wherein at least one longitudinal segment of the channel wall includes an intermediate segment connecting a pair of hot segments and/or cold segments with a segment length greater than an average segment length of the respective hot segments and cold segments.

12. The electrical module as claimed in claim 1, wherein the channel wall has a local recess approximate at least one hot segment via which the fluid working medium can directly flow through the electrical component.

13. An apparatus for cooling a heat source, the apparatus comprising:
an annularly closed elongated media channel for circulating a fluid working medium in a closed circuit;
a channel wall bounding the annularly closed media channel, the channel wall divided, at least in part, in a local longitudinal direction, into a plurality of alternating hot segments and cold segments;
wherein each of the hot segments is disposed approximate the heat source and thermally coupled thereto to enable heat to be removed from the heat source by local heat input into the fluid working medium via the respective hot segment of the channel wall;
wherein a transition region is defined between each of the adjacent hot segments and cold segments; and
a flow-directing element is arranged in at least some of the transition regions to define a preferred direction to a thermally driven transport of the fluid working medium by local heat input.
